(19) United States
(12) Patent Application Publication
(10) Pub. No.: US 2006/0027901 A1
(43) Pub. Date: Feb. 9, 2006

(54) Stacked chip package with exposed lead-frame bottom surface

(76) Inventors: Ming-Sung Tsai, Hsin-Chu (TW); Jin-Ho Kim, Hsin-Chu (TW); Eul-Chul Jang, Hsin-Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/913,319

(22) Filed: Aug. 9, 2004

(51) Int. Cl. H01L 23/48

(52) U.S. Cl. 257/676; 257/777; 257/787

(57) ABSTRACT

A stacked chip package with exposed lead-frame bottom surface is disclosed. The stacked chip package includes a first die encapsulated in an encapsulated molding compound, which is mounted on an active surface of a second die. A bottom surface of the second die is mounted to a top surface of a die supporting section of the lead-frame. The bottom surface of the die supporting section is exposed outside the encapsulated molding compound. A plurality of bonding wires electrically interconnect the die pads of the first die and the second die to the corresponding lead fingers. Moreover, each lead finger of the lead-frame is preferably formed with a deflected structure with a bent section, which enables the dimension size of the stacked chip package to get more compact.

### BACKGROUND OF THE INVENTION

1. Field of the Invention

The present invention relates to a stacked chip package, and more particularly to a compact structure of the stacked chip package with an exposed lead-frame bottom surface.

2. Description of the Prior Art

Integrated circuit chips are widely applied in many electronic equipment, computer systems, and instruments. Integrated circuit chip is compact and can fit in small space. By applying chips, the dimensions of conventional electronic equipment can be largely reduced. However, as the development of technology, various advanced portable devices such as laptop, mobile phone, personal digital assistants (PDAs), that are compact and light, require even smaller chips. Practically, the dimension of chip is a critical factor to the design of many portable devices.

In general, to shrink the dimension of an IC chip or to stack the IC chips to form a stacked chip package can meet the demand for more compact design. Due to the limitation of the component density per unit area, it would be hard to shrink the dimension of an individual IC chip. Alternatively, to apply a stacked chip package structure to the IC chips is a more feasible way to get a more compact dimension.

In accordance with the above-mentioned fact and demand, different stacked chip packages are developed. Those stack package devices are disclosed in such as U.S. Pat. Nos. 6,087,722, 5,804,874, 6,437,447 and 5,814,881.

All those prior arts comprise stacked chip package structures, but the structure designs of those prior arts are different. Referring to FIG. 1, a cross sectional view of a conventional stacked chip package is shown, in which a first die 12 and a second die 13 are encapsulated in an encapsulated molding compound 11. The first die 12 is provided with a plurality of die pads 121 disposed on the active surface thereof. The bottom surface of the first die 12 is mounted on a top surface of a die supporting section 141 of a lead-frame 14 by applying die attached material 122. The second die 13 has a plurality of die pads 131 disposed on an active surface and the bottom surface of the second die 13 is mounted on the bottom surface of the die supporting section 141 of the lead-frame 14 by applying die attached material 132. The die pads 121 of the first die 12 and the die pads 131 of the second die 13 are electrically connected to the corresponding lead fingers 142 of the lead-frame 14 by means of the bonding wires 15, 16. Then, the first die 12, the second die 13, the lead fingers 142, and the bonding wires 15, 16 are wholly encapsulated in the encapsulated molding compound 11.

Referring to FIG. 2, a cross sectional view of another conventional stacked package is shown, in which a first die 22 and a second die 23 are encapsulated in an encapsulated molding compound 21. The first die 22 has a plurality of die pads 221 disposed on an active surface and the bottom surface of the first die 22 is mounted on a top surface of the second die 23 by applying die attached material 222. The second die 23 has a plurality of die pads 231 disposed on an active surface and the bottom surface of the second die 23 is mounted on a top surface of the die supporting section 241 of the lead-frame 24 by applying die attached material 232. The die pads 221 of the first die 22 and die pads 231 of the second die 23 are electrically connected to the corresponding lead fingers 242 of the lead-frame 24 by means of the bonding wires 25, 26. Then, the first die 22, the second die 23, the lead fingers 242, and the bonding wires 25, 26 are wholly encapsulated in the encapsulated molding compound 21.

Although various prior stacked chip structures are developed and known, and they are indeed effective in shrinking the dimension of the IC package, they are found to inevitably increase the complexity to the structures and the inconveniences to the production processes. Moreover, in the conventional stacked chip packages, the fabricated chips are wholly encapsulated in the encapsulated molding compound, and therefore heat dissipation of the chips is not good.

Thus, it is an important issue for the semi-conductor industry to develop a stacked chip package that is smaller in size, simple to manufacture and has good heat dissipation. It is desired to develop such a stacked chip package to fulfill the above-mentioned demands.

### SUMMARY OF THE INVENTION

Therefore, a primary object of the present invention is to provide a structure of a stacked chip package with exposed lead-frame bottom surface, in which the die supporting section of the lead-frame is exposed outside the encapsulated molding compound. Such a structure renders the stacked chip package with enhanced heat dissipation, so as to enable the chips to perform optimally and stably.

Another object of the present invention is to provide a structure of a stacked chip package, which renders the stacked chip package with shrunk dimension and good heat dissipation, such that the stacked chip package can dissipate heat effectively and is more compact in dimension.

A further object of the present invention is to provide a packing technology for stacked chip package, which profits the enhancement of heat dissipation and the simplification of implementation. The packing process applies the conventional wire bonding process for electrically interconnecting the die pads to the corresponding lead fingers of the lead-frame by means of the bonding wires, and no custom-made process is needed.

To achieve the above-identified objects, in accordance with the present invention, there is provided a stacked chip package with exposed lead-frame bottom surface. The stacked chip package includes a first die encapsulated in an encapsulated molding compound, which is mounted on an active surface of a second die. A bottom surface of the second die is mounted to a top surface of a die supporting section of the lead-frame. The bottom surface of the die supporting section is exposed outside the encapsulated molding compound. A plurality of bonding wires electrically interconnect the die pads of the first die and the second die to the corresponding lead fingers of the lead-frame.

In a preferred embodiment of the present invention, the lead finger of the lead-frame is formed with a deflected ladder structure comprising a bent section extending between a first and a second lateral section of the lead finger, which enables the dimension size of the stacked chip package to get more compact.

Compared with the conventional stacked chip packages, the present invention overcomes the heat dissipation problem encountered in the conventional stacked chip packages and enables the IC chips applying a stacked chip package according to the present invention to profit the enhancement of heat dissipation, so as to enable chips to perform optimally and stably. Moreover, the stacked chip package according to the present invention profits the effective reduction in the dimension size of the stacked chip package. In terms of an aspect of process, no custom-made process is needed, so at to simultaneously profit the simplification of the implementation.

The foregoing aspects and many of the attendant advantages of this invention will become more apparent to those skilled in the art by reference to the following detailed description, when taken in conjunction with the accompanying drawings, in which:

### BRIEF DESCRIPTION OF THE DRAWINGS

FIG. 1 is a cross sectional view of a conventional stacked chip package;

FIG. 2 is a cross sectional view of another conventional stacked chip package;

FIG. 3 is a cross sectional view of a stacked chip package according to a first embodiment of the present invention;

FIG. 4 is a top plan view of the lead-frame of FIG. 3 according to the first embodiment of the present invention;

FIG. 5 is a cross sectional view taken along line 5-5 of FIG. 4;

FIG. 6 is a cross sectional view of the stacked chip package according to a second embodiment of the present invention;

FIG. 7 is a top plan view of the lead-frame of FIG. 6 according to the second embodiment of the present invention;

FIG. 8 is a cross sectional view taken along line 8-8 of FIG. 7; and

FIG. 9 is a cross sectional view of the stacked chip package according to a third embodiment of the present invention.

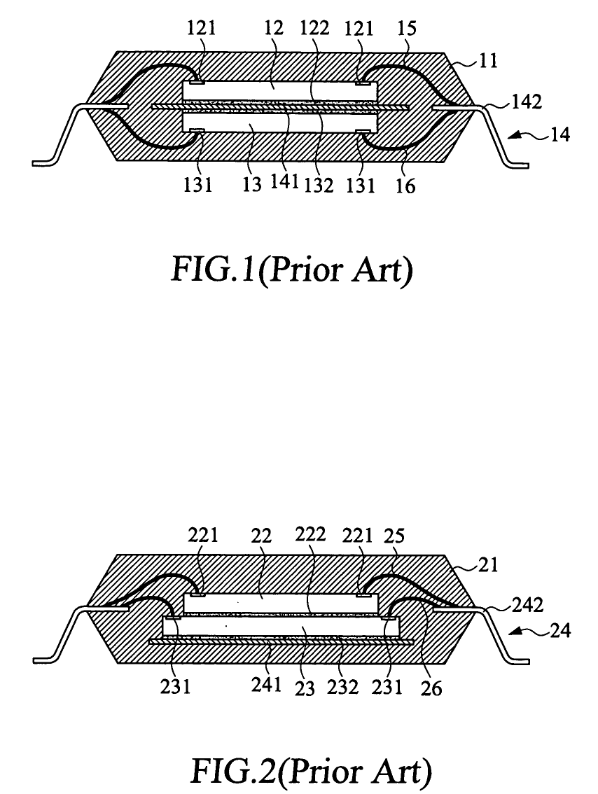

### DETAILED DESCRIPTION OF THE PREFERRED EMBODIMENTS

The following is a description of the present invention. The invention will firstly be described with reference to one exemplary structure. Some variations will then be described as well as advantages of the present invention. A preferred structure then is discussed.

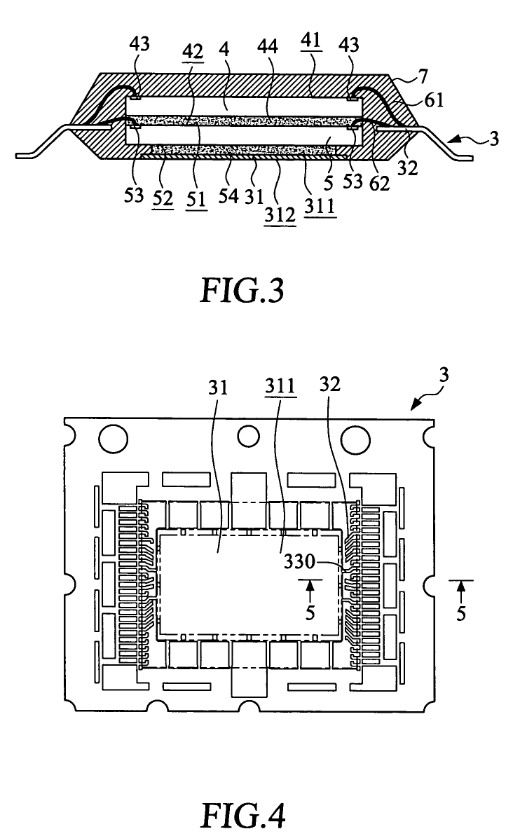

Referring to FIG. 3, a cross sectional view of a stacked chip package according to a first embodiment of the present invention is shown. It shows that the stacked chip package comprises a lead-frame 3 which includes a die supporting section 31 and a plurality of lead fingers 32.

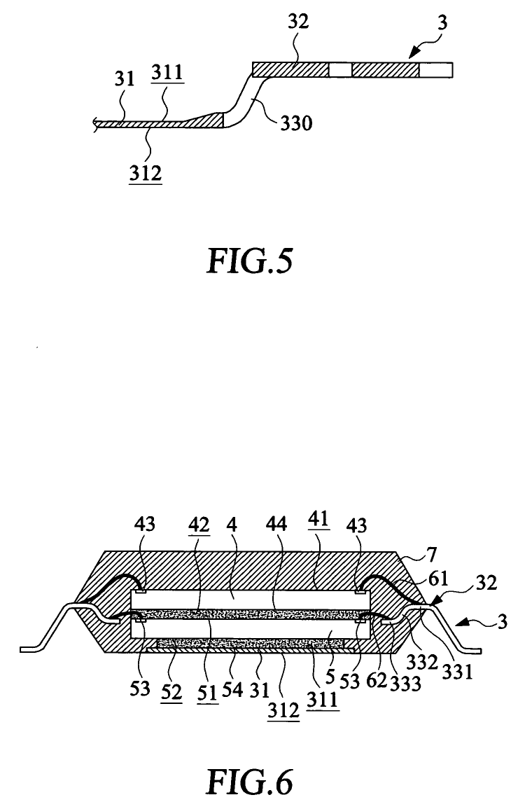

FIG. 4 is a top plan view of the lead-frame 3 of FIG. 3, and FIG. 5 is a cross sectional view taken along line 5-5 of FIG. 4. The die supporting section 31 of the lead-frame 3 is adapted to support and bear a die mounted thereon, which has a top surface 311 and a bottom surface 312. Each lead finger 32 is extended in a direction from the lead-frame 3 toward the die supporting section 31. The die supporting section 31 of the lead-frame 3 vertically deviates from the lead fingers 32 with a distance, forming an offset section 330 therebetween.

The stacked chip package comprises a first die 4 having an active surface 41 and a bottom surface 42. A plurality of die pads 43 are disposed on the active surface 41. Also, a second die 5 having an active surface 51 and a bottom surface 52 is provided at the stacked chip package. A plurality of die pads 53 are disposed on the active surface 51 of the second die 5.

The bottom surface 42 of the first die 4 is mounted on the active surface 51 of the second die 5 by means of a die attached material 44, and the bottom surface 52 of the second die 5 is mounted to the die supporting section 31 of the lead-frame 3 by applying a die attached material 54, forming a stacked or a dual-chip structure.

Then, a plurality of bonding wires 61 respectively interconnect the die pads 43 of the first die 4 to the corresponding lead fingers 32 of the lead-frame 3. Meanwhile, a plurality of bonding wires 62 respectively interconnect the die pads 53 of the second die 5 to the corresponding lead fingers 32 of the lead-frame 3, so that the electronic signal of both the first die 4 and the second die 5 can be transmitted to an outer circuit (not shown) via the connection between the bonding wires 61 and 62 and the corresponding lead fingers 32.

Finally, the die supporting section 31, the lead fingers 32, the first die 4, the second die 5, the bonding wires 61 and 62 are encapsulated in an encapsulated molding compound 7, wherein the bottom surface 312 of the die supporting section 31 is fully or partially exposed outside the encapsulated molding compound 7.

According to the present invention, the bottom surface 312 of the die supporting section 31 is exposed outside the encapsulated molding compound 7 and this arrangement enhances heat dissipation from the stacked chip package. Furthermore, the thickness of the stacked chip package can be significantly reduced, because the bottom surface of the lead-frame 3 is not encapsulated in the encapsulated molding compound 7, so that the structure renders the stacked chip package a more compact dimension. Such a structure also benefits the production processes. In wire bonding process, because both the active surfaces of the first and second dies 4, 5, where the die pads 43, 53 are located, are arranged faceup, the bonding between the bonding wires 61, 62 and the first die 4 and the second die 5, respectively can be easily accomplished.

In the above-mentioned description with reference to the first embodiment of the present invention, it shows that the enhancement of heat dissipation, the effective reduction in the dimension size of the stacked chip package and the facilitation of the wire bonding process are achievable simultaneously by applying the present invention to improve the structure of the stacked chip package. Hence, the present invention is very practical in industry application.

Referring to FIG. 6, a cross sectional view of a stacked chip package according to a second embodiment of the present invention is shown. It shows that a stacked chip package that is substantially similar to the first embodiment of the present invention described above. Like numeral references are used to identify elements that are similar or identical in the two embodiments.

In the second embodiment, the stacked chip package comprises a lead-frame 3, a die supporting section 31, a plurality of lead fingers 32, a first die 4, a second die 5 and an encapsulated molding compound 7. The bottom surface 312 of the die supporting section 31 is also exposed outside the encapsulated molding compound 7. The second embodiment is different from the first embodiment in that the lead fingers 32 of the lead-frame 3 have an improved structure.

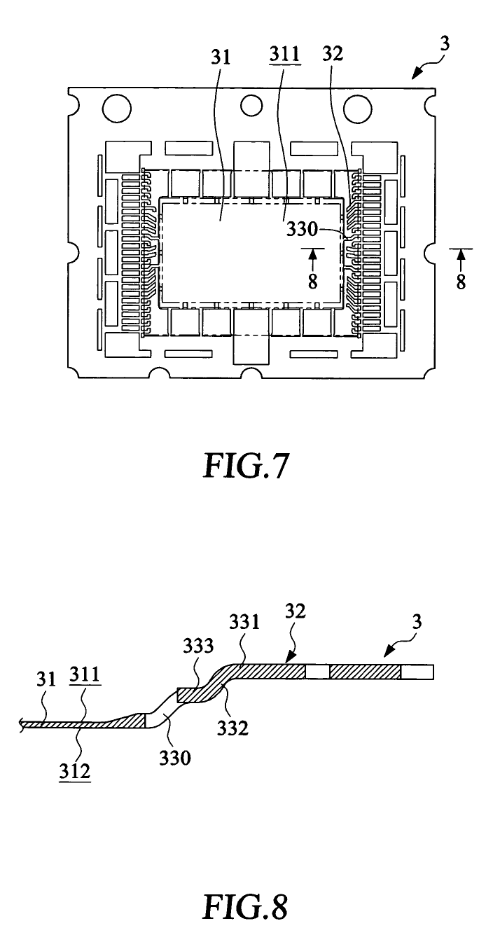

Referring to FIG. 7, a top plan view of the lead-frame 3 according to the second embodiment of the present invention is shown. FIG. 8 is a cross sectional view taken along line 8-8 of FIG. 7.

In the design of the lead fingers 32 according to the second embodiment of the present invention, a first lateral section 331 of the lead fingers 32 is extended from the lead finger 32 toward the first die 4 and the second die 5. A bonding wire 61 interconnects the top of the first lateral section 331 to a corresponding die pad 43 disposed on an active surface 41 of the first die 4.

Moreover, a bent section 332 is extended from an inner end of the first lateral section 331 toward the second die 5, forming a deflected structure biasing to the second die 5. Then, a second lateral section 333 is extended from the inside end of the bent section 332, and the free end of the second lateral section 333 is stretched out close to the position of the second die 5. A bonding wire 62 interconnects a top of the second lateral section 333 to a corresponding die pad 53 disposed on an active surface 51 of the first die 5. The die supporting section 31 of the lead-frame 3 vertically deviates from the lead fingers 32 with a distance, forming an offset section 330 therebetween.

The second embodiment of the present invention possesses the advantages of good heat dissipation, small thickness and simple production process, as that of the first embodiment of the present invention. The second embodiment is further reduced in width as a result of the ladder shape structure of the lead fingers 32 formed with the first lateral section 331, the bent section 332 and the second lateral section 333.

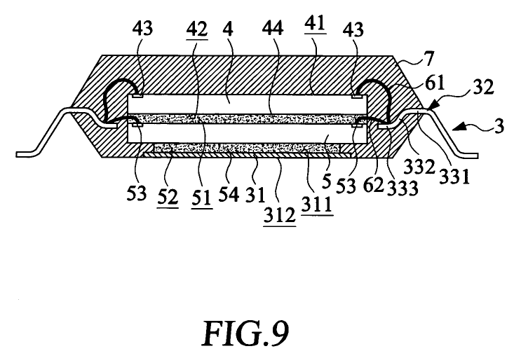

Please refer to FIG. 9 which shows a cross-sectional view of the stacked chip package according to a third embodiment of the present invention. The third embodiment is similar to the second embodiment of FIG. 6. As shown, the lead fingers 32 of the lead-frame 3 of the third embodiment also comprises a first lateral section 331, a bent section 332, a second lateral section 333 and a pair of bonding wires 61, 62. The third embodiment is different from the second embodiment in that one end of the bonding wire 61 is connected with a top surface of the second lateral section 333 and the other end of the bonding wire 61 is connected with a corresponding die pad 43 on the active surface 41 of the first die 4. Similarly, one end of the bonding wire 62 is connected with the top surface of the second lateral section 333 and the other end of the bonding wire 62 is connected with a corresponding die pad 53 on the active surface 51 of the second die 5.

Referring to an overview of the above-mentioned description, the present invention is indeed practical for industry application. Although the present invention has been described with reference to the preferred embodiments of the device thereof, it is apparent to those skilled in the art that a variety of modifications and changes may be made without departing from the scope of the present invention which is intended to be defined by the appended claims.

1. A stacked chip package, comprising;
an encapsulated molding compound;
a lead-frame comprising a die supporting section and a plurality of lead fingers, the die supporting section having a top surface and a bottom surface, each lead finger being extended toward the die supporting section;
a first die encapsulated in the encapsulated molding compound, which comprises an active surface, a bottom surface and a plurality of die pads disposed on the active surface of the first die;
a second die encapsulated in the encapsulated molding compound, which comprises an active surface, a bottom surface and a plurality of die pads disposed on the active surface of the second die; and
a plurality of bonding wires respectively interconnecting the die pads of the first die and the second die to corresponding lead fingers;
wherein the bottom surface of the first die is mounted on the active surface of the second die, the bottom surface of the second die is mounted on the top surface of the die supporting section of the lead-frame, and the bottom surface of the die supporting section is exposed outside the encapsulated molding compound; and
wherein said each lead finger includes an inner end extending in said encapsulated molding compound and an external portion extending outside said encapsulated molding compound, said external portion of said each lead finger co-extending substantially in the same plane with said bottom surface of said die supporting section exposed outside said encapsulated molding compound.

2. The stacked chip package as claimed in claim 1, wherein each of the lead fingers of the lead-frame comprises:
a first lateral section extended from said inner end of the lead finger to the die supporting section, said first lateral section being connected to the die pad of the first die by a bonding wire;
a bent section formed at an inner end of the first lateral section; and
a second lateral section formed at an inner end of the bent section, said second lateral section being connected to the die pad of the second die by a bonding wire.

3. The stacked chip package as claimed in claim 2, wherein the bent section is formed with a deflected structure having an outer end extended from an inner end of the first lateral section and an inner end biasing toward the second die.

4. The stacked chip package as claimed in claim 1, wherein the bottom surface of the first die is mounted on the active surface of the second die by applying a die attached material therebetween.

5. The stacked chip package as claimed in claim 1, wherein the bottom surface of the second die is mounted on the top surface of the die supporting section of the lead-frame by applying a die attached material therebetween.

6. A stacked chip package, comprising:
an encapsulated molding compound;
a lead-frame comprising a die supporting section and a plurality of lead fingers, the die supporting section having a top surface and a bottom surface, each lead finger being extended toward the die supporting section;
at least one die encapsulated in the encapsulated molding compound, which comprises an active surface, a bottom surface and a plurality of die pads disposed on the active surface of said at least one die; and
a plurality of bonding wires respectively interconnecting the die pads of said at least one die to the lead fingers;
wherein the bottom surface of said at least one die mounted on the top surface of the die supporting section of the lead-frame, and the bottom surface of the die supporting section is exposed outside the encapsulated molding compound; and
wherein said each lead finger includes an inner end extending in said encapsulated molding compound and an external portion extending outside said encapsulated molding compound, said external portion of said each lead finger co-extending substantially in the same plane with said bottom surface of said die supporting section exposed outside said encapsulated molding compound.

7. The stacked chip package as claimed in claim 6, wherein each of the lead fingers of the lead-frame comprises:
a first lateral section extended from said inner end of the lead finger to the die supporting section;
a bent section formed at an inner end of the first lateral section; and
a second lateral section formed at an inner end of the bent section; a respective die pad of said at least one die being connected to said first lateral section or said second lateral section by a bonding wire.

8. The stacked chip package as claimed in claim 7, wherein the bent section is formed with a deflected structure having an outer end extended from said inner end of the first lateral section and an inner end biasing toward the die.

9. The stacked chip package as claimed in claim 6, wherein the bottom surface of said at least one die is mounted to the top surface of the die supporting section of the lead-frame by applying a die attached material therebetween.
